(19) United States
(12) Patent Application Publication
(10) Pub. No.: US 2026/0013179 A1
(43) Pub. Date: Jan. 8, 2026

(54) VERTICAL NANOSHEET TRANSISTOR WITH BACKSIDE SOURCE/DRAIN CONTACT

(71) Applicant: International Business Machines Corporation, Armonk, NY (US)

(72) Inventors: Gopal Sankar Kenath, Troy, NY (US); Tao Li, Slingerlands, NY (US); Ruilong Xie, Niskayuna, NY (US); Nicolas Jean Loubet, GUILDERLAND, NY (US)

(21) Appl. No.: 18/761,550

(22) Filed: Jul. 2, 2024

(51) Int. Cl. H01L 29/423; H01L 21/762; H01L 21/8234; H01L 27/088; H01L 29/06; H01L 29/08; H01L 29/66; H01L 29/775; H01L 29/786

(52) U.S. Cl. CPC H10D 30/6735; H01L 21/76224; H10D 30/014; H10D 30/43; H10D 30/6757; H10D 62/121; H10D 62/151; H10D 64/017; H10D 64/018; H10D 64/021; H10D 84/0128; H10D 84/013; H10D 84/038; H10D 84/83

(57) ABSTRACT

Embodiments of present invention provide a semiconductor structure. The semiconductor structure includes a vertical nanosheet transistor, the vertical nanosheet transistor includes a first and a second vertical nanosheet horizontally separated by a gap; a metal gate surrounding the first and the second vertical nanosheet respectively at a top, a bottom, and a left and a right sidewall thereof; and a first and a second source/drain region in contact with the first and the second vertical nanosheet; where the first and the second vertical nanosheet and the gap between the first and the second vertical nanosheet are vertically above a raised portion of a backside inter-level dielectric layer. A method of manufacturing the semiconductor structure is also provided.

### BACKGROUND

The present application relates to manufacturing of semiconductor integrated circuits. More particularly, it relates to method of forming vertical nanosheet transistor with backside source/drain contact and the structure formed thereby.

As semiconductor industry moves towards smaller node, different types of field-effect-transistors (FETs) are introduced that are aggressively scaled to fit into reduced footprint or real estate, which is often dictated by the node size, with increased device density. For example, fin-type transistors and nanosheet based transistors are introduced to help further reduce footprint. On the other hand, some power supply and/or signal routing functions for the transistors are being moved to the backside of the substrate, resulting in the introduction of backside power distribution network (BSPDN) as a mean to further enhance the device density.

With the progress in BSPDN development, there is a need to develop new types of transistors such as vertical nanosheet transistors and integrate such vertical nanosheet transistors with the BSPDN process such as, for example, develop a process of forming source/drain contact for the vertical nanosheet transistors.

### SUMMARY

Embodiments of present invention provide a semiconductor structure. The semiconductor structure includes a vertical nanosheet transistor, the vertical nanosheet transistor includes a first and a second vertical nanosheet horizontally separated by a gap; a metal gate surrounding the first and the second vertical nanosheet respectively at a top, a bottom, and a left and a right sidewall thereof; and a first and a second source/drain region in contact with both the first vertical nanosheet and the second vertical nanosheet, where the first and the second vertical nanosheet and the gap between the first and the second vertical nanosheet are vertically above a raised portion of a backside inter-level dielectric (BILD) layer.

According to one embodiment, the semiconductor structure further includes a sidewall spacer that separates the metal gate from the first source/drain region at a left side of the first vertical nanosheet and at a right side of the second vertical nanosheet, and an inner spacer that separates the metal gate from the first source/drain region at the gap between the first and the second vertical nanosheet.

In one embodiment, the inner spacer is materially different from the sidewall spacer or has a thickness that is different from a thickness of the sidewall spacer.

In another embodiment, the raised portion of the BILD layer has a left sidewall that is substantially aligned with the left sidewall of the first vertical nanosheet; has a right sidewall that is substantially aligned with the right sidewall of the second vertical nanosheet; and has a substantially flat top surface.

According to another embodiment, the semiconductor structure further includes one or more shallow-trench-isolation (STI) regions being embedded in the BILD layer, the one or more STI regions surrounding the raised portion of the BILD layer.

According to yet another embodiment, the semiconductor structure further includes a backside source/drain contact that contacts the second source/drain region of the vertical nanosheet transistor.

According to a further embodiment, the semiconductor structure further includes a placeholder underneath the first source/drain region of the vertical nanosheet transistor, the placeholder being embedded in the BILD layer and materially different from the BILD layer.

In one embodiment, the vertical nanosheet transistor is a first vertical nanosheet transistor, further comprising a second vertical nanosheet transistor, wherein a metal gate of the second vertical nanosheet transistor is insulated from the metal gate of the first vertical nanosheet transistor by a gate-cut structure, the gate-cut structure extends into a shallow-trench-isolation (STI) region embedded in the BILD layer.

Embodiments of present invention also provide a method of forming a semiconductor structure. The method includes forming a set of vertical nanosheets on top of a substrate, the set of vertical nanosheets includes a first and a second vertical nanosheet that are separated by a protective layer; forming a set of sacrificial gates covering portions of the set of vertical nanosheets; forming sidewall spacers at sidewalls of the set of sacrificial gates; recessing the set of vertical nanosheets between the set of sacrificial gates to create end surfaces of the set of vertical nanosheets and end surfaces of the protective layer; epitaxially growing a source/drain region from the end surfaces of the set of vertical nanosheets; replacing the set of sacrificial gates with a set of metal gates; and forming a backside source/drain contact from a backside of the substrate, the backside source/drain contact contacting a bottom surface of the source/drain region.

According to one embodiment, the method further includes creating recesses at the end surfaces of the protective layer; and filling the recesses with a dielectric material to form inner spacers, the inner spacers being at least partially underneath the sidewall spacers.

According to another embodiment, the method further includes, before epitaxially growing the source/drain region, forming one or more placeholders in the substrate between the set of sacrificial gates.

According to yet another embodiment, the method further includes selectively etching the substrate, using the first and the second vertical nanosheet and the protective layer between the first and the second vertical nanosheet as an etch mask, to create one or more recesses; and filling the one or more recesses with a dielectric material to form one or more shallow-trench-isolation (STI) regions.

In one embodiment, forming the backside source/drain contact includes replacing the substrate with a backside inter-level dielectric (BILD) layer; creating an opening in the BILD layer to expose a placeholder; selectively removing the exposed placeholder to further extend the opening thereby exposing a bottom surface of the source/drain region; and filling the extended opening with a conductive material to form the backside source/drain contact.

According to a further embodiment, the method further includes performing a gate-cut in the set of metal gates to form a gate-cut structure that extends into a shallow-trench-isolation (STI) region embedded in the substrate.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, and 1C to FIGS. 17A, 17B, and 17C are demonstrative illustrations of cross-sectional views and FIG. 1D to FIG. 17D are simplified top views of a semiconductor structure at various steps of manufacturing thereof according to embodiments of present invention; and

FIG. 18 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

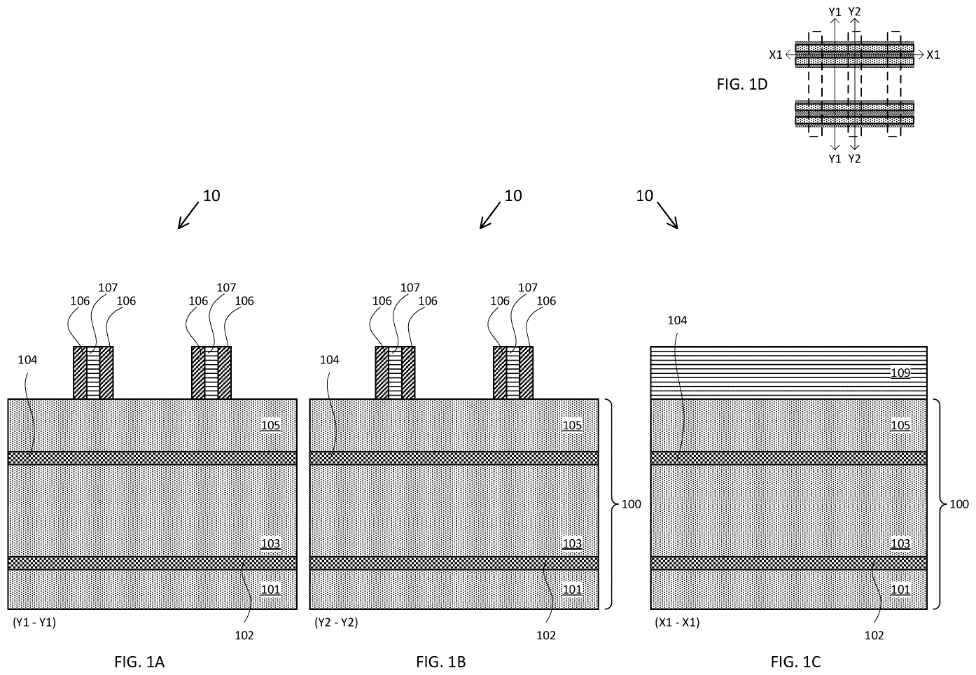

FIGS. 1A, 1B, and 1C are demonstrative illustrations of different cross-sectional views and FIG. 1D is a simplified top view of a semiconductor structure at a step of manufacturing thereof according to one embodiment of present invention. More specifically, FIG. 1A illustrates a cross-sectional view of a semiconductor structure 10 with a cross-section made along a line Y1-Y1 as being illustrated in FIG. 1D. In other words, the cross-section shown in FIG. 1A is made across source/drain regions of transistors in a direction along the width of gates of the transistors. FIG. 1B illustrates a cross-sectional view of the semiconductor structure 10 with a cross-section made along a line Y2-Y2 as being illustrated in FIG. 1D. In other words, the cross-section shown in FIG. 1B is made across the gates of the transistors in a direction along the width of the gates of the transistors. FIG. 1C illustrates a cross-sectional view of the semiconductor structure 10 with a cross-section made along a line X1-X1 as being illustrated in FIG. 1D. In other words, the cross-section shown in FIG. 1C is made across the gates of the transistors in a direction along the length of the gates of the transistors.

As its purpose is to illustrate locations of the various cross-sections whose views are illustrated in FIGS. 1A, 1B, and 1C, FIG. 1D may selectively illustrate only key elements such as, for example, nanosheets, gates, and source/drain regions that were previously made, yet to be made, and/or whose view may be obstructed but the illustration thereof may help understand locations of the above various cross-sections. Other elements such as cap layer, sidewall spacers, interlevel dielectric layers, etc. may not necessarily be illustrated in order not to overcrowd FIG. 1D, and to the extent that their omission from FIG. 1D does not hinder description of embodiments of present invention, which are mainly provided hereinafter with reference to FIGS. 1A, 1B, and 1C.

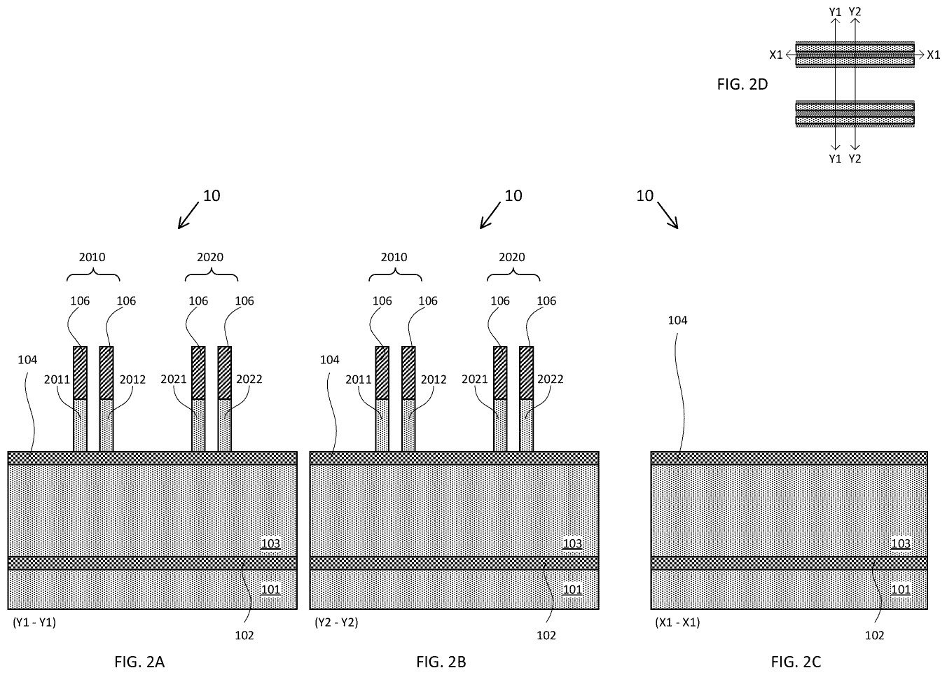

Likewise, FIGS. 2A, 2B, and 2C to FIGS. 17A, 17B, and 17C are demonstrative cross-sectional views and FIG. 2D to FIG. 17D are simplified top views of the semiconductor structure, at different manufacturing steps, illustrated in manners similar to FIGS. 1A, 1B, 1C, and 1D respectively.

Embodiments of present invention provide forming a semiconductor structure 10, which is demonstratively illustrated hereinafter to be formed to include multiple vertical nanosheet transistors. More particularly, as is illustrated in FIGS. 1A, 1B, 1C, and 1D, embodiments of present invention provide receiving or providing a substrate 100, forming one or more mandrels 107 on top of the substrate 100, and forming one or more sets of sidewall spacers 106 at sidewalls of the one or more mandrels 107.

The substrate 100 may be a composite semiconductor substrate to include a bulk substrate 101; a first etch-stop layer (ESL) 102 on top of the bulk substrate 101; a first semiconductor layer 103 on top of the first ESL 102; a second ESL 104 on top of the first semiconductor layer 103; and a second semiconductor layer 105.

The bulk substrate 101 may be a silicon (Si) substrate, a germanium (Ge) substrate, a silicon-germanium (SiGe) substrate, or other suitable substrate such as, for example, a dielectric substrate. In one embodiment, the first and the second semiconductor layer 103 and 105 may be a Si layer and the first and the second ESL 102 and 104 may be a SiGe layer that provide an etch selectivity different from an etch selectivity of the first and the second Si layer 103 and 105. Applying the difference in etch selectivity strategically, during a process of forming vertical nanosheets, the second semiconductor layer 105 may be etched or patterned, relative to the second ESL 104 in a selective etch process that stops at the second ESL 104. Similarly, during a process of forming backside contacts or backside contact vias, the bulk substrate 101 may be etched or removed, relative to the first ESL 102 in a selective etch process that stops at the first ESL 102.

In one embodiment, the one or more mandrels 107 may be formed by first forming a layer of mandrel material such as, for example, amorphous silicon (a-Si), amorphous carbon, polycrystalline silicon (Poly-Si), polycrystalline silicon-germanium (Poly-SiGe), amorphous silicon-germanium (a-SiGe), polycrystalline germanium (Poly-Ge), and/or amorphous germanium (a-Ge) on top of the second semiconductor layer 105 and patterning the layer of mandrel material through a lithographic patterning process followed by a selective etch process. After forming the one or more mandrels 107, the one or more sets of sidewall spacers 106 may be formed by first depositing a conformal layer of material such as, for example, silicon-oxide (SiOx), silicon-nitride (SiN), silicoboron-carbonitride (SiBCN), silicon-oxycarbonitride (SiOCN), silicon-carbonitride (SiCN), silicon-oxycarbide (SiOC) covering the one or more mandrels 107 and a top surface of the second semiconductor layer 105. Next, a directional and/or anisotropic etch process, such as a reactive-ion-etch (RIE) process, may be applied to remove portions of the conformal layer of material, particularly horizontal portions of the conformal layer of material, leaving only vertical portions of the conformal layer of material at sidewalls of the one or more mandrels 107 to form the one or more sets of sidewall spacers 106.

FIGS. 2A, 2B, and 2C are demonstrative illustrations of different cross-sectional views and FIG. 2D is a simplified top view of a semiconductor structure at a step of manufacturing thereof according to one embodiment of present invention. More specifically, following the step illustrated at FIGS. 1A, 1B, 1C, and 1D, embodiments of present invention provide selectively removing the one or more mandrels 107 leaving only the one or more sets of sidewall spacers 106 on top of the second semiconductor layer 105 to form a mask pattern for forming one or more sets of vertical nanosheets. Next, the mask pattern formed by the one or more sets of sidewall spacers 106 may be transferred onto the second semiconductor layer 105 through a selective etch process such as, for example, a RIE process. For example, the selective etch process may etch and remove portions of the second semiconductor layer 105, except those portions that are directly covered by the one or more sets of sidewall spacers 106, until the second ESL 104 underneath the second semiconductor layer 105 is reached or exposed. In one embodiment, the selective etch process may etch partially into the second ESL 104 as well.

The one or more sets of vertical nanosheets formed thereby may include, for example, a first set of vertical nanosheets 2010 that includes vertical nanosheets 2011 and 2012 and a second set of vertical nanosheets 2020 that includes vertical nanosheets 2021 and 2022. Vertical nanosheets 2011 and 2012 are horizontally separated by a gap and vertical nanosheets 2021 and 2022 are horizontally separated by a gap as well. The gap corresponds to a width of the now-removed mandrels 107.

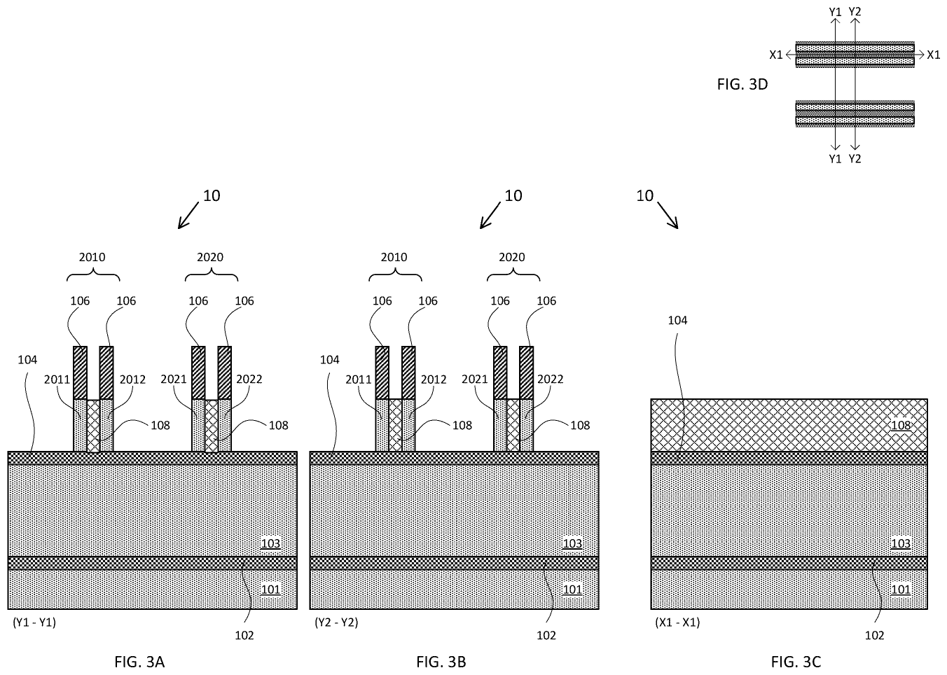

FIGS. 3A, 3B, and 3C are demonstrative illustrations of different cross-sectional views and FIG. 3D is a simplified top view of a semiconductor structure at a step of manufacturing thereof according to one embodiment of present invention. More specifically, following the step illustrated at FIGS. 2A, 2B, 2C, and 2D, embodiments of present invention provide covering portions of the second ESL 104 between the two sidewall spacers 106 of each set of sidewall spacers 106 with a protective layer 108. In other words, the protective layer 108 may be formed in between the vertical nanosheets 2011 and 2012 of the first set of vertical nanosheets 2010 and in between the vertical nanosheets 2021 and 2022 of the second set of vertical nanosheets 2020. The protective layer 108 may be a layer of sacrificial material such as, for example, a layer of silicon-germanium (SiGe).

The protective layer 108 may be formed through first depositing a conformal layer of the sacrificial material covering the vertical nanosheets 2011 and 2012 of the first set of vertical nanosheets 2010, the vertical nanosheets 2021 and 2022 of the second set of vertical nanosheets 2020, the one or more sets of sidewall spacers 106, and on top of the second ESL 104. Alternately, a layer of the sacrificial material may be blanketly deposited to cover the sidewall spacers 106, the vertical nanosheets 2011, 2012, 2021, and 2022, and the second ESL 104. The conformal layer may pinch off, or the blanket layer may fill, between the one or more sets of sidewall spacers 106; between the vertical nanosheets 2011 and 2012; and between the vertical nanosheets 2021 and 2022. Next, an etch-back process, such as a selective and/or anisotropic etch process, may be applied to remove portions of the conformal layer, for example, at outer sidewalls of each set of sidewall spacers 106 (i.e., sidewalls not between the sidewall spacers 106 in the set); at outer sidewalls of the first and the second set of vertical nanosheets 2010 and 2020 (i.e., sidewalls not between the vertical nanosheets 2011 and 2012 and not between the vertical nanosheets 2021 and 2022); and on top of the second ESL 104. On the other hand, the portion of the conformal layer between the sidewall spacers 106 of each set of sidewall spacers 106 may be recessed or etched back to have a height that, in one embodiment, becomes substantially same as a height of the first set of vertical nanosheets 2010 and the second set of vertical nanosheets 2020.

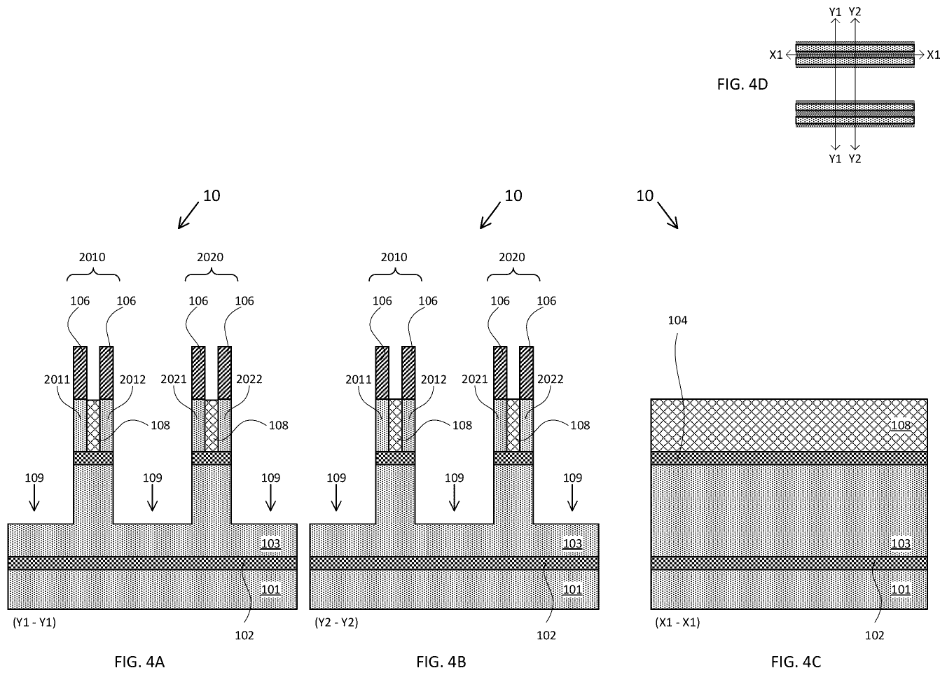

FIGS. 4A, 4B, and 4C are demonstrative illustrations of different cross-sectional views and FIG. 4D is a simplified top view of a semiconductor structure at a step of manufacturing thereof according to one embodiment of present invention. More specifically, following the step illustrated at FIGS. 3A, 3B, 3C, and 3D, embodiments of present invention provide recessing or etching the second ESL 104 and subsequently recessing or etching the first semiconductor layer 103 underneath the second ESL 104, in areas between the different sets of vertical nanosheets such as between the first set of the vertical nanosheets 2010 and the second set of the vertical nanosheets 2020. During the etch process, the protective layer 108 of sacrificial material, such as SiGe, may protect the second ESL 104 and the underneath first semiconductor layer 103 from being etched.

In one embodiment, the recessing or etching may etch into the first semiconductor layer 103, create raised portions of the first semiconductor layer 103 directly underneath the one or more sets of vertical nanosheets 2010 and 2020, and create a set of recesses 109 surrounding the raised portions of the first semiconductor layer 103. The raised portions of the first semiconductor layer 103 may have a substantially flat top surface; and may have a left edge that is substantially aligned with an outer sidewall of, for example, the left sidewall of the vertical nanosheet 2011 of the first set of vertical nanosheets 2010 or the left sidewall of the vertical nanosheet 2021 of the second set of vertical nanosheets 2020. The raised portions of the first semiconductor layer 103 may have a right edge that is substantially aligned with an outer sidewall of, for example, the right sidewall of the vertical nanosheet 2012 of the first set of vertical nanosheets 2010 or the right sidewall of the vertical nanosheet 2022 of the second set of vertical nanosheets 2020. Here, outer sidewalls refer to sidewalls of a set of vertical nanosheets that are not between the vertical nanosheets in the set. The set of recesses 109 may be created between the different sets of vertical nanosheets such as between the first set of vertical nanosheets 2010 and the second set of vertical nanosheets 2020. After the etch process, a portion of the first semiconductor layer 103 may remain on top of the first ESL 102.

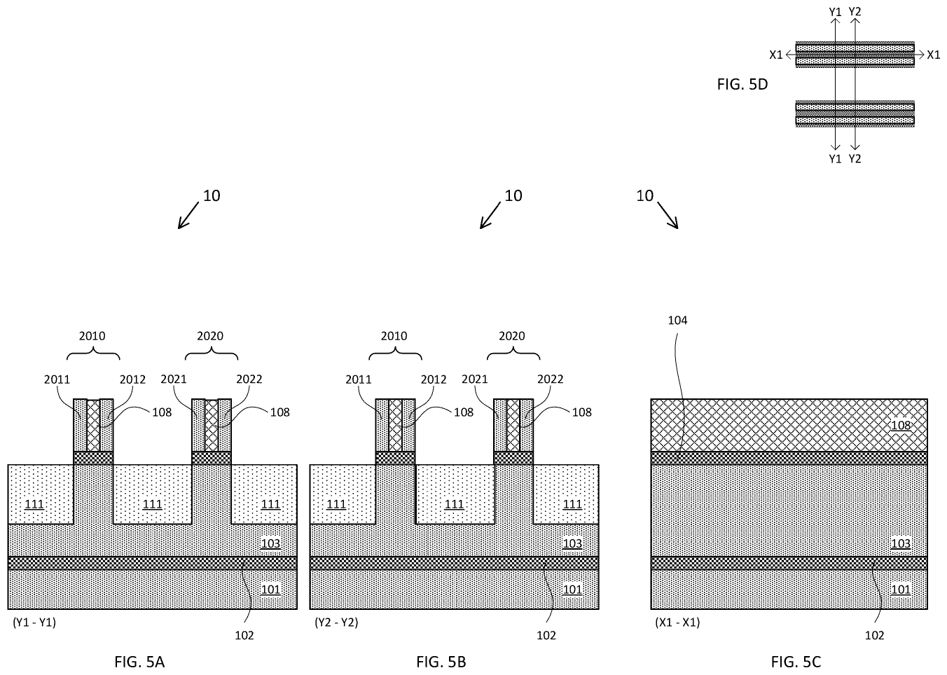

FIGS. 5A, 5B, and 5C are demonstrative illustrations of different cross-sectional views and FIG. 5D is a simplified top view of a semiconductor structure at a step of manufacturing thereof according to one embodiment of present invention. More specifically, following the step illustrated at FIGS. 4A, 4B, 4C, and 4D, embodiments of present invention provide forming a set of shallow-trench-isolation (STI) regions 111 in the set of recesses 109 by depositing a layer of dielectric material therein. In one embodiment, the dielectric material may include, for example, SiOx, SIN, SiBCN, SiOCN, SiCN, SiOC, flowable-oxide, or other suitable dielectric materials. The deposition of the dielectric material may be made through, for example, a chemical-vapor-deposition (CVD) process, a physical-vapor-deposition (PVD) process, or an atomic-layer-deposition (ALD) process. In one embodiment, the dielectric material may be initially deposited to a level above, thereby covering, the first set of vertical nanosheets 2010 and the second set of vertical nanosheets 2020. A chemical-mechanical-polishing (CMP) process may subsequently be applied to planarize a top surface of the deposited dielectric material. Next, the planarized dielectric material may then be recessed until a top surface of the dielectric material becomes to be substantially coplanar with a top surface of the first semiconductor layer 103, thereby forming the set of STI regions 111.

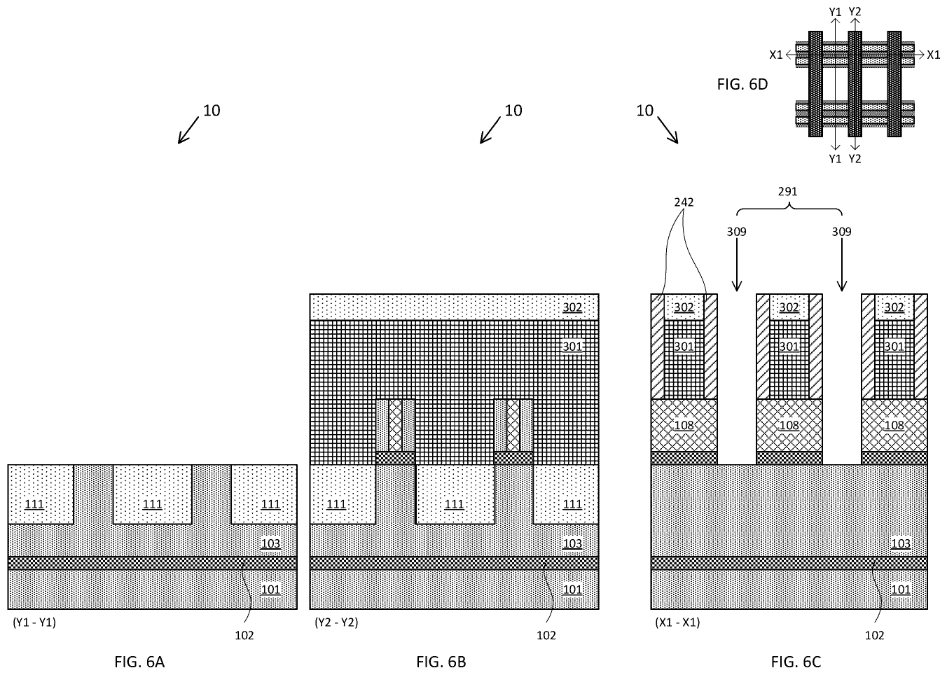

FIGS. 6A, 6B, and 6C are demonstrative illustrations of different cross-sectional views and FIG. 6D is a simplified top view of a semiconductor structure at a step of manufacturing thereof according to one embodiment of present invention. More specifically, following the step illustrated at FIGS. 5A, 5B, 5C, and 5D, embodiments of present invention provide forming a set of sacrificial gates 301 on top of the one or more sets of vertical nanosheets such as the first set of vertical nanosheets 2010 and the second set of vertical nanosheets 2020, and on top of the set of STI regions 111. The set of sacrificial gates 301 may be formed by first depositing or forming a blanket layer of sacrificial gate material such as, for example, polysilicon (P—Si) on top of the first set of vertical nanosheets 2010 and the second set of vertical nanosheets 2020 and on top of the set of STI regions 111; forming a set of gate masks 302 on top of the blanket layer of sacrificial gate material; and transferring the pattern of the set of gate masks 302 onto the blanket layer of sacrificial gate material thereby forming the set of sacrificial gates 301.

After forming the set of sacrificial gates 301, sidewall spacers 242 may be formed at sidewalls of each of the set of sacrificial gates 301. The sidewall spacers 242 may be formed by depositing a conformal layer of sidewall spacer material covering the set of sacrificial gates 301, and subsequently applying a directional and/or anisotropic etch process to remove horizontal portions of the conformal layer of sidewall spacer material leaving only the vertical portion thereof to form the sidewall spacers 242. In one embodiment, the sidewall spacer material may include, for example, SiOx, SiN, SiBCN, SiOCN, or other suitable dielectric or non-dielectric materials.

After forming the sidewall spacers 242, embodiments of present invention provide recessing portions of the first and the second set of vertical nanosheets 2010 and 2020 that are not covered by the set of sacrificial gates 301 and their sidewall spacers 242. In other words, the set of sacrificial gates 301 and sidewall spacers 242 may be used as an etch mask in a selective etch process, such as a reactive-ion-etch (RIE) process, to recess or etch the vertical nanosheets 2011, 2012, 2021, and 2022 as well as the protective layer 108 between the vertical nanosheets 2011 and 2012 and between the vertical nanosheets 2021 and 2022. The recess or etch process may create or expose end surfaces of the first set of vertical nanosheets 2010 and the second set of vertical nanosheets 2020, as well as end surfaces of the protective layer 108. The selective etch process may also etch and remove portions of the second ESL 104 exposed by the removal of the vertical nanosheets 2011, 2012, 2021, and 2022 and the protective layer 108, thereby creating a set of openings 309 between the set of sacrificial gates 301, where source/drain regions may be formed later for one or more vertical nanosheet transistors such as, for example, a first vertical nanosheet transistor 291.

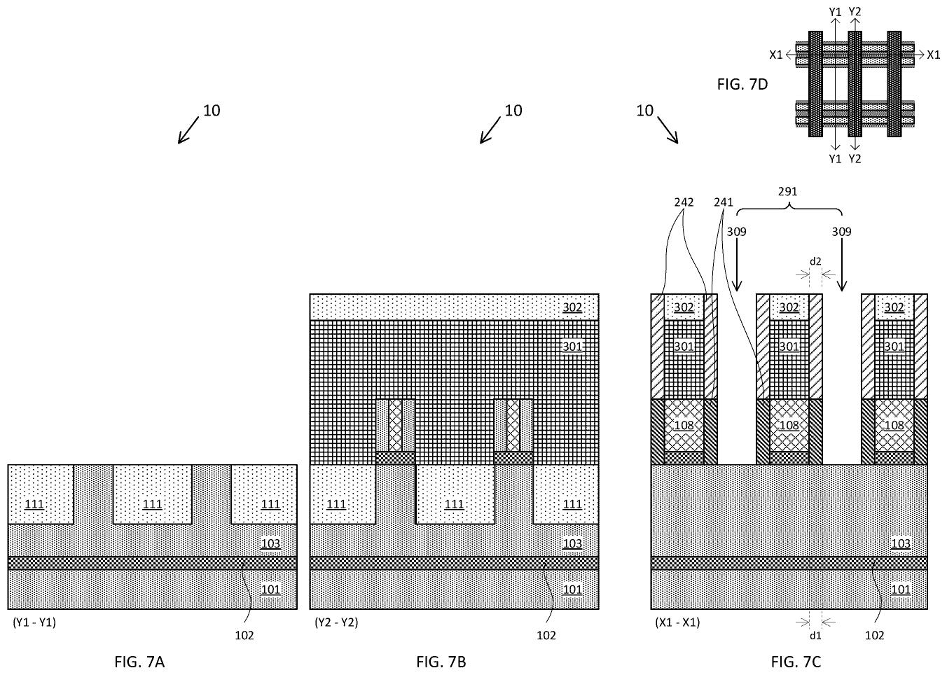

FIGS. 7A, 7B, and 7C are demonstrative illustrations of different cross-sectional views and FIG. 7D is a simplified top view of a semiconductor structure at a step of manufacturing thereof according to one embodiment of present invention. More specifically, following the step illustrated at FIGS. 6A, 6B, 6C, and 6D, embodiments of present invention provide performing an indentation process to etch the exposed end surfaces of the protective layer 108 to create recesses that is at least partially underneath the sidewall spacers 242. The recesses are subsequently filled with a dielectric material, such as SiN, SiOx, SiBCN, or SiOCN to form inner spacers 241. In one embodiment, the inner spacers 241 may have a first thickness or width d1 and the sidewall spacers 242 may have a second thickness or width d2, and the first thickness d1 may be different from the second thickness d2 to be thicker or thinner than the second thickness d2. In another embodiment, the dielectric material used to form the inner spacers 241 may be different from the sidewall spacer material of the sidewall spacers 242. In other words, the inner spacers 241 and the sidewall spacers 242 may be materially different.

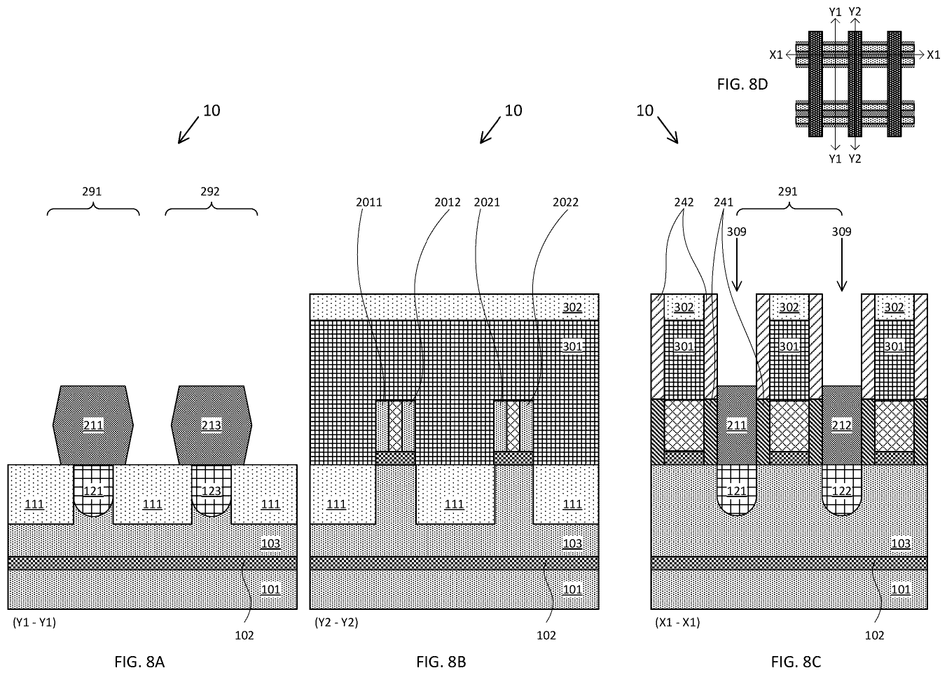

FIGS. 8A, 8B, and 8C are demonstrative illustrations of different cross-sectional views and FIG. 8D is a simplified top view of a semiconductor structure at a step of manufacturing thereof according to one embodiment of present invention. More specifically, following the step illustrated at FIGS. 7A, 7B, 7C, and 7D, embodiments of present invention provide further recessing the first semiconductor layer 103 through the set of openings 309 between the set of sacrificial gates 301 to create recesses in the first semiconductor layer 103. The recesses are next filled with a sacrificial material such as SiGe, or other suitable material, thereby forming one or more placeholders such as, for example, a first placeholder 121, a second placeholder 122, and a third placeholder 123. In one embodiment, material of the first, the second, and the third placeholders 121, 122, and 123 may be different from that of the one or more STI regions 111 such that they may have different etch selectivity. After forming the placeholders, in one embodiment, a barrier layer (not shown) may be grown on top of the first, the second, and the third placeholders 121, 122, and 123 such that the barrier layer protects the S/D regions later through etch selectivity during a recess process at a backside processing stage.

After forming the placeholders, embodiments of present invention provide epitaxially growing one or more source/drain (S/D) regions in the set of openings 309 at the end surfaces of the vertical nanosheets 2011 and 2012 and at the end surfaces of the vertical nanosheets 2021 and 2022. The one or more S/D regions may include a first S/D region 211 and a second S/D region 212 of the first vertical nanosheet transistor 291, and a third S/D region 213 and a fourth S/D region of a second vertical nanosheet transistor 292. The first S/D region 211 may be separated from the sacrificial gate 301, which may be replaced later with a metal gate, at a left side of the vertical nanosheet 2011 and at a right side of the vertical nanosheet 2012 by the sidewall spacer 242; and may be separated from the protective layer 108 between the vertical nanosheet 2011 and the vertical nanosheet 2012 by the inner spacer 241. Similarly, the third S/D region 213 may be separated from the sacrificial gate 301 at a left side of the vertical nanosheet 2021 and at a right side of the vertical nanosheet 2022 by the sidewall spacer 242; and may be separated from the protective layer 108 between the vertical nanosheet 2021 and the vertical nanosheet 2022 by the inner spacer 241.

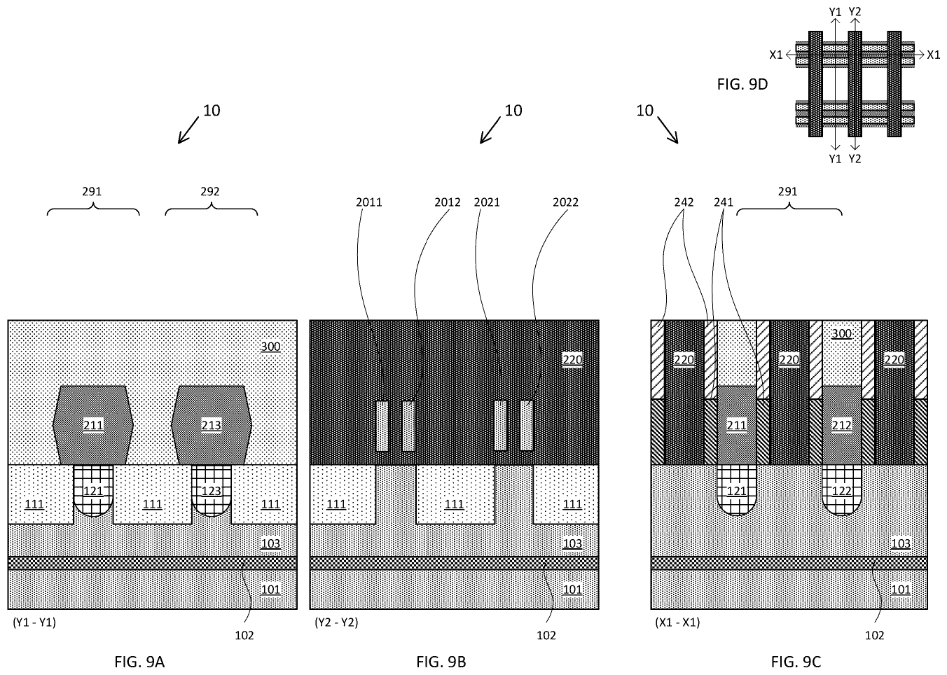

FIGS. 9A, 9B, and 9C are demonstrative illustrations of different cross-sectional views and FIG. 9D is a simplified top view of a semiconductor structure at a step of manufacturing thereof according to one embodiment of present invention. More specifically, following the step illustrated at FIGS. 8A, 8B, 8C, and 8D, embodiments of present invention provide filling the remaining portions of the set of openings 309 between the set of sacrificial gates 301 with a dielectric layer 300 and subsequently applying a CMP process to planarize the dielectric layer 300. The CMP process may also remove the gate mask 302 to expose the set of sacrificial gates 301. Next, embodiments of present invention provide performing a replacement-metal-gate (RMG) process to replace the set of sacrificial gates 301 with a set of metal gates 220. For example, embodiments of present invention may provide selectively removing the set of sacrificial gates 301, which may be for example polysilicon, and the protective layer 108 to expose the one or more sets of vertical nanosheets that may serve as channel regions of one or more vertical nanosheet transistors; forming a layer of gate dielectric to cover the one or more sets of vertical nanosheets; forming one or more layers of work-function-metal (WFM) on top of the gate dielectric layer; and forming one or more layers of conductive materials on top of the WFM layers, thereby forming the set of metal gates 220.

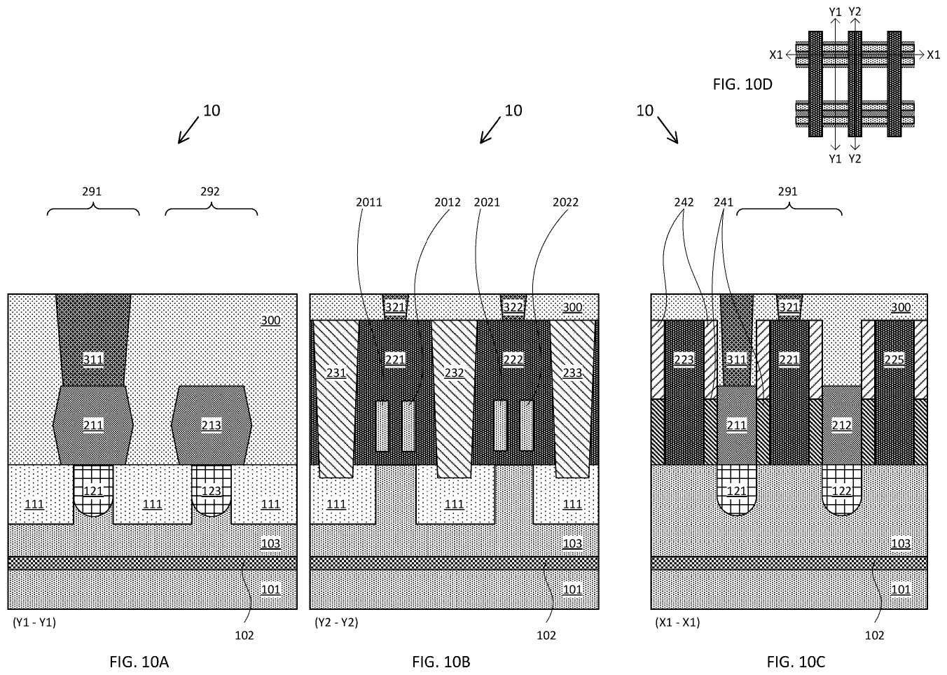

FIGS. 10A, 10B, and 10C are demonstrative illustrations of different cross-sectional views and FIG. 10D is a simplified top view of a semiconductor structure at a step of manufacturing thereof according to one embodiment of present invention. More specifically, following the step illustrated at FIGS. 9A, 9B, 9C, and 9D, embodiments of present invention provide performing a gate-cut process to cut one or more of the set of metal gates 220, which are shared metal gates, into a plurality of non-shared metal gates such as a first metal gate 221 of the first vertical nanosheet transistor 291, a second metal gate 222 of the second vertical nanosheet transistor 292, and other non-shared metal gates such as metal gates 223 and 225. The gate-cut process may create a set of gate-cut structures between the plurality of metal gates such as a gate-cut structures 231, 232, and 233. The gate-cut structures 231, 232, and 233 may downwardly extend into the one or more STI regions 111, thereby completely insulating, for example, the first metal gate 221 from the second metal gate 222.

In one embodiment, the first source/drain region 211 of the first vertical nanosheet transistor 291 may be separated from the metal gate 221, longitudinally along a length direction of the metal gate 221, by either the inner spacer 241 or the sidewall spacer 242. More particularly, in regions horizontally to a left side of the vertical nanosheet 2011 and to a right side of the vertical nanosheet 2012 as illustrated in FIG. 10B, the first source/drain region 211 of the first vertical nanosheet transistor 291 may be separated from the metal gate 221 by the sidewall spacer 242. Here, horizontally means along a width direction of the metal gate 221. In the meantime, in a region horizontally between the first and the second vertical nanosheet 2011 and 2012, the first source/drain region 211 of the first vertical nanosheet transistor 291 may be separated from the metal gate 221 by the inner spacer 241. The second source/drain region 212 of the first vertical nanosheet transistor 291 may be separated from the metal gate 221 by either the sidewall spacer 242 or the inner spacer 241 as well, in a manner similar to the first source/drain region 211. The same may be said for the second vertical nanosheet transistor 292.

After forming the set of shared metal gates 220 and/or the plurality of non-shared metal gates 221, 222, 223, and 225 through the gate-cut process, embodiments of present invention provide depositing new dielectric material on top of, thereby extending, the dielectric layer 300 to a level above top surfaces of the plurality of metal gates. A CMP process may then be applied to planarize a top surface of the dielectric layer 300. Next, a first set of via openings may be created in the dielectric layer 300 and the first set of via openings may then be filled with a conductive material to form one or more frontside S/D contacts such as, for example, a frontside S/D contact 311. A second set of via openings may be created in the dielectric layer 300 and the second set of via openings are also filled with the conductive material to form one or more frontside gate contacts such as, for example a first gate contact 321 contacting the first metal gate 221 and a second gate contact 322 contacting the second metal gate 222. The conductive material used in forming the frontside S/D contacts and frontside gate contacts may include, for example, copper (Cu), aluminum (Al), ruthenium (Ru), cobalt (Co), tungsten (W), or other suitable conductive materials.

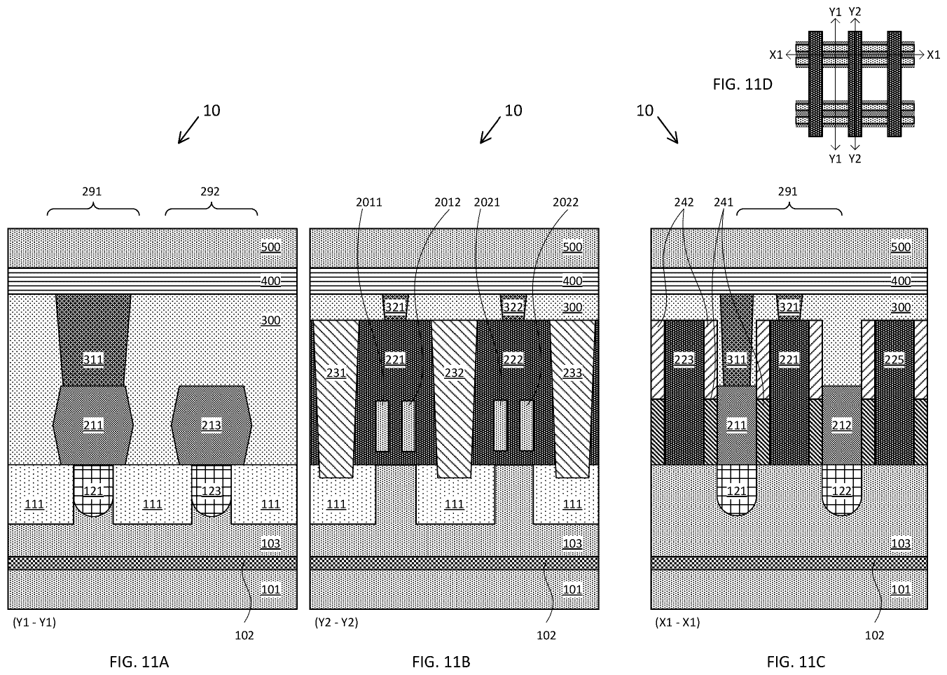

FIGS. 11A, 11B, and 11C are demonstrative illustrations of different cross-sectional views and FIG. 11D is a simplified top view of a semiconductor structure at a step of manufacturing thereof according to one embodiment of present invention. More specifically, following the step illustrated at FIGS. 10A, 10B, 10C, and 10D, embodiments of present invention provide forming a back-end-of-line (BEOL) structure 400 on top of the dielectric layer 300. The BEOL structure 400 may include a plurality of metal levels embedded in a plurality of dielectric layers. The BEOL structure 400 may provide power supply and/or signal routing functions, for example, to the first and the second vertical nanosheet transistors 291 and 292 through, for example, the frontside S/D contact 311 and the frontside gate contacts 321 and 322.

After forming the BEOL structure 400, embodiments of present invention provide attaching, for example through a wafer bonding process, a carrier wafer 500 onto the BEOL structure 400. The carrier wafer 500 may be used as a handling wafer such that the semiconductor structure 10 may be flipped upside-down and be processed next from a backside of the substrate 100.

Hereinafter, various processes may be performed from the backside of the substrate 100 and the description will be consistent with the process. Nevertheless, for the purpose of illustration, the various cross-sections of the semiconductor structure 10 will still be shown in an upside-up manner, together with the description of the features thereof.

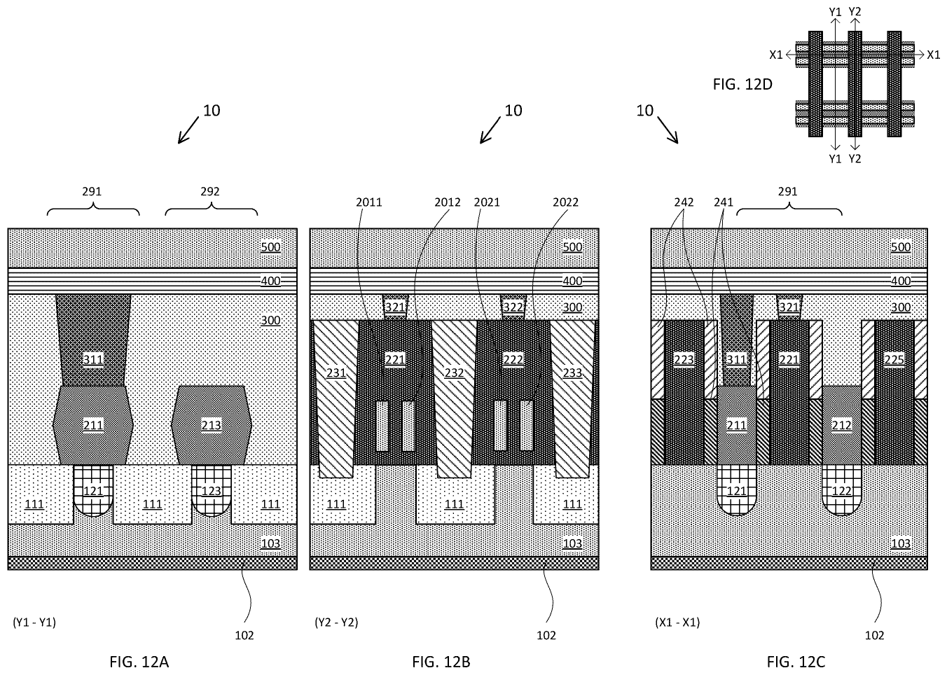

FIGS. 12A, 12B, and 12C are demonstrative illustrations of different cross-sectional views and FIG. 12D is a simplified top view of a semiconductor structure at a step of manufacturing thereof according to one embodiment of present invention. More specifically, following the step illustrated at FIGS. 11A, 11B, 11C, and 11D, embodiments of present invention provide removing the bulk substrate 101 from the backside of the substrate 100. The removal of the bulk substrate 101 may be made through, for example, a grinding process, a CMP process, a wet or dry etch process, or a combination thereof. The removal of the bulk substrate 101 may expose the first ESL 102. Here the use of the first ESL 102, through material difference and thus etch selectivity, results in the removal of the bulk substrate 101 being performed in a controlled manner.

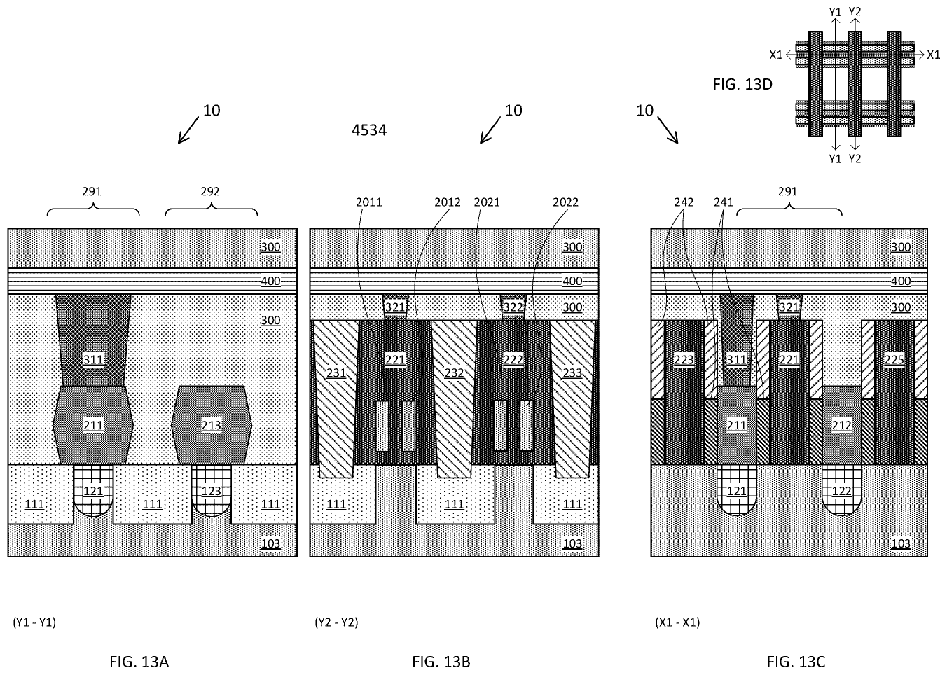

FIGS. 13A, 13B, and 13C are demonstrative illustrations of different cross-sectional views and FIG. 13D is a simplified top view of a semiconductor structure at a step of manufacturing thereof according to one embodiment of present invention. More specifically, following the step illustrated at FIGS. 12A, 12B, 12C, and 12D, embodiments of present invention provide selectively removing the first ESL 102 to expose the underneath first semiconductor layer 103.

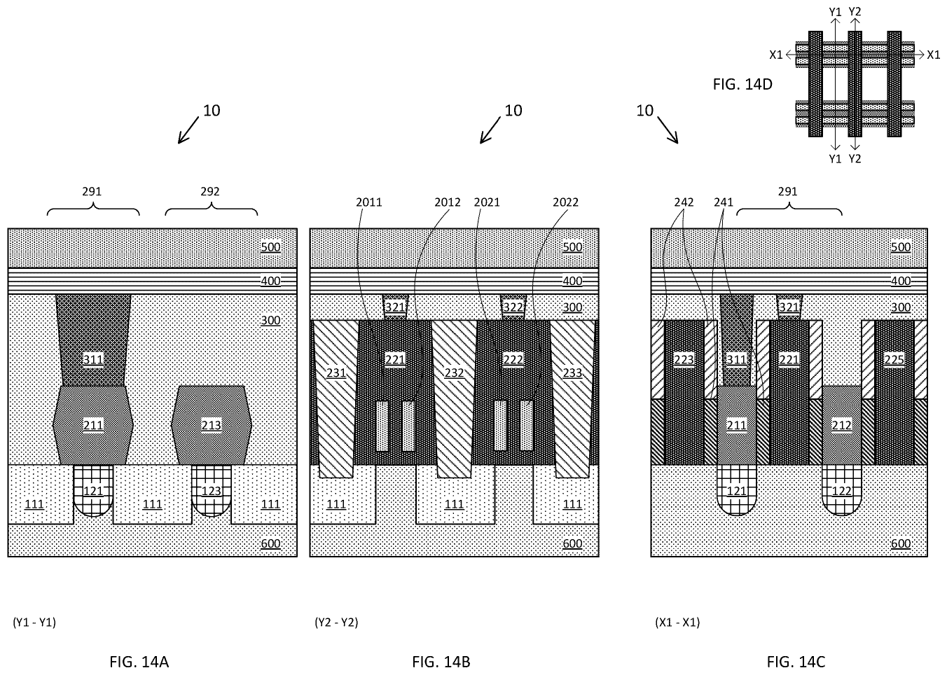

FIGS. 14A, 14B, and 14C are demonstrative illustrations of different cross-sectional views and FIG. 14D is a simplified top view of a semiconductor structure at a step of manufacturing thereof according to one embodiment of present invention. More specifically, following the step illustrated at FIGS. 13A, 13B, 13C, and 13D, embodiments of present invention provide selectively removing the first semiconductor layer 103, relative to the one or more STI regions 111 and the one or more placeholders 121, 122, and 123. Embodiments of present invention then provide depositing a backside inter-level dielectric (BILD) layer 600 covering the exposed one or more STI regions 111 and the one or more placeholders 121, 122, and 123. In other words, embodiments of present invention provide replacing the first semiconductor layer 103 with a BILD layer 600, and the BILD layer 600 formed thereby may have one or more raised portions directly underneath the one or more sets of vertical nanosheets 2010 and 2020. Like the first semiconductor layer 103, a left edge of the one or more raised portions of the BILD layer 600 may be substantially aligned with a first outer sidewall of a set of vertical nanosheets such as a left sidewall of the vertical nanosheet 2011 of the first set of nanosheets 2010. Likewise, a right edge of the one or more raised portions of the BILD layer 600 may be substantially aligned with a second outer sidewall of a set of vertical nanosheets such as a right sidewall of the vertical nanosheet 2012 of the first set of nanosheets 2010. The one or more raised portions of the BILD layer 600 may have a substantially flat top surface as well. The BILD layer 600 may be a layer of dielectric material and the dielectric material may include, for example, SiOx, SiN, SiBCN, SiOCN, or other dielectric material.

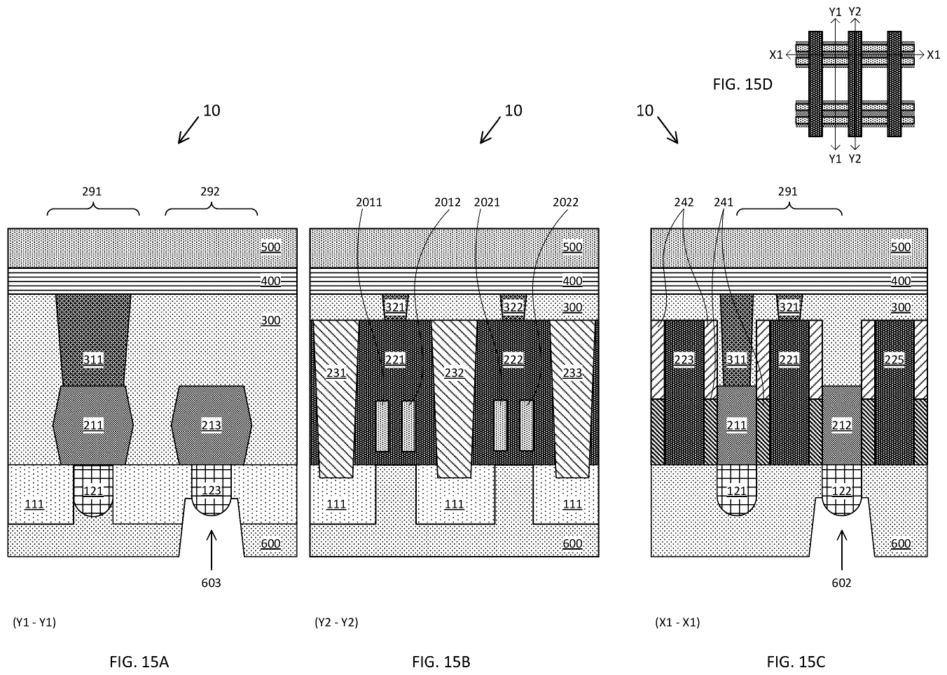

FIGS. 15A, 15B, and 15C are demonstrative illustrations of different cross-sectional views and FIG. 15D is a simplified top view of a semiconductor structure at a step of manufacturing thereof according to one embodiment of present invention. More specifically, following the step illustrated at FIGS. 14A, 14B, 14C, and 14D, embodiments of present invention provide creating one or more openings in the BILD layer 600 to expose one or more placeholders embedded in or underneath the BILD layer 600. The one or more openings such as a first and a second opening 602 and 603 may be created through a lithographic patterning process and a selective etch process. The first opening 602 may expose the second placeholder 122 underneath the second source/drain region 212 of the first vertical nanosheet transistor 291. The second opening 603 may expose the third placeholder 123 underneath the third source/drain region 213 of the second vertical nanosheet transistor 292.

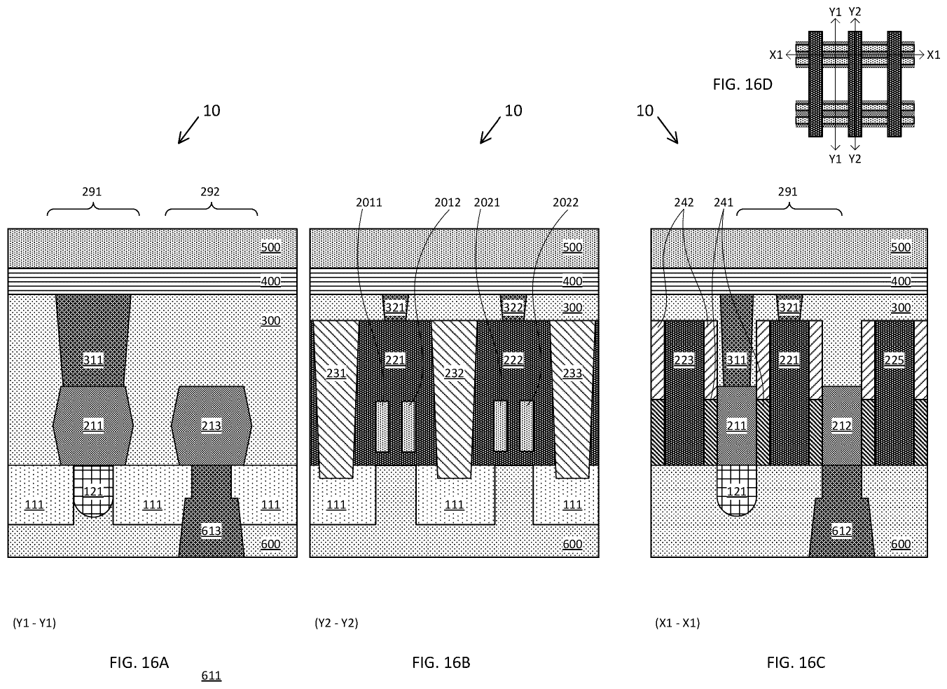

FIGS. 16A, 16B, and 16C are demonstrative illustrations of different cross-sectional views and FIG. 16D is a simplified top view of a semiconductor structure at a step of manufacturing thereof according to one embodiment of present invention. More specifically, following the step illustrated at FIGS. 15A, 15B, 15C, and 15D, embodiments of present invention provide filling the first opening 602 and the second opening 603 with a conductive material such as Cu, Al, Ru, Co, or W thereby forming a first backside S/D contact 612 and a second backside S/D contact 613.

In one embodiment, the first and the second backside S/D contact 612 and 613 may be partially surrounded by the one or more STI regions 111 in a first direction along a width of the metal gate 221 and may be embedded in the BILD layer 600 in a second direction along a length of the metal gate 221. The second direction is perpendicular to the first direction.

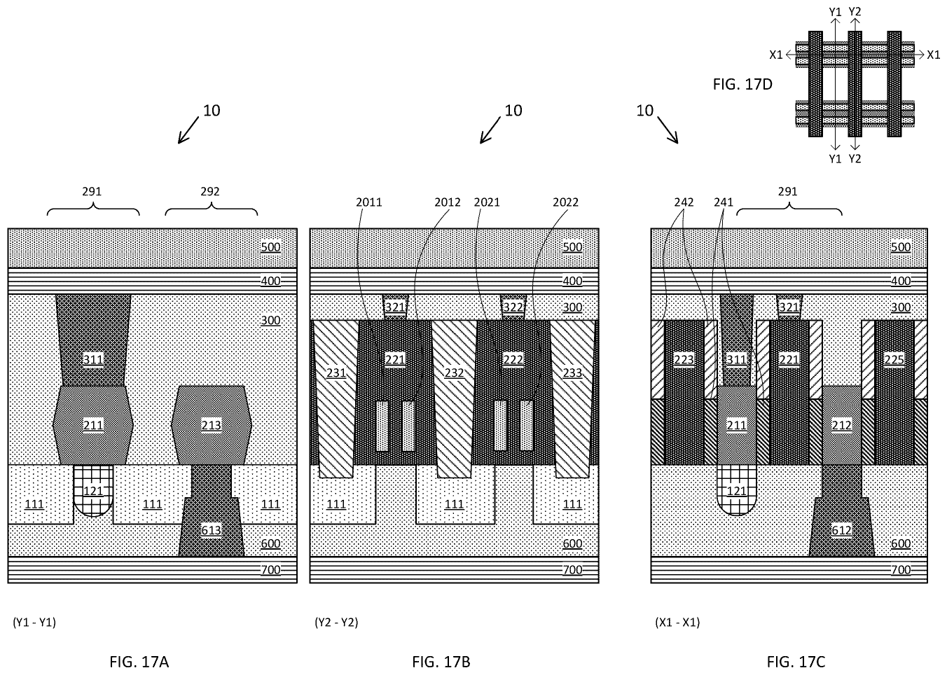

FIGS. 17A, 17B, and 17C are demonstrative illustrations of different cross-sectional views and FIG. 17D is a simplified top view of a semiconductor structure at a step of manufacturing thereof according to one embodiment of present invention. More specifically, following the step illustrated at FIGS. 16A, 16B, 16C, and 16D, embodiments of present invention provide forming a backside interconnect structure 700 on top of the BILD layer 600. The backside interconnect structure 700 may include one or more metal levels that provide, for example, power supply to the first and the second vertical nanosheet transistors 291 and 292 through, for example, the first and the second backside S/D contacts 612 and 613.

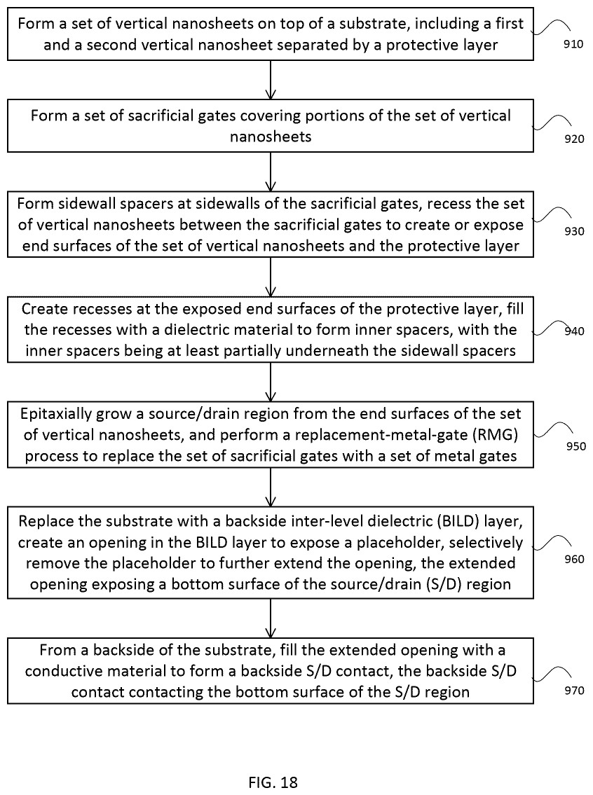

FIG. 18 is a demonstrative illustration of a flow-chart of a method of manufacturing a semiconductor structure according to embodiments of present invention. The method includes (910) forming a set of vertical nanosheets on top of a substrate, the set of vertical nanosheets includes a first and a second vertical nanosheet that are separated by a protective layer; (920) forming a set of sacrificial gates covering portions of the set of vertical nanosheets; (930) forming sidewall spacers at sidewalls of the sacrificial gates, recessing the set of vertical nanosheets between the sacrificial gates to create or expose end surfaces of the set of vertical nanosheets and end surfaces of the protective layer; (940) creating recesses at the exposed end surfaces of the protective layer and filling the recesses with a dielectric material to form inner spacers, with the inner spacers being at least partially underneath the sidewall spacers; (950) epitaxially growing a source/drain (S/D) region from the end surfaces of the set of vertical nanosheets, and performing a replacement-metal-gate (RMG) process to replace the set of sacrificial gates with a set of metal gates; (960) replacing the substrate with a backside inter-level dielectric (BILD) layer, creating an opening in the BILD layer to expose a placeholder, selectively removing the placeholder to further extend the opening to expose a bottom surface of the S/D region; and (970) from a backside of the substrate, filling the extended opening with a conductive material to form a backside S/D contact, the backside S/D contact contacting the bottom surface of the S/D region.

Various examples may possibly be described by one or more of the following features in the following numbered clauses:
Clause 1: A semiconductor structure comprising a vertical nanosheet transistor, the vertical nanosheet transistor comprising a first and a second vertical nanosheet horizontally separated by a gap; a metal gate surrounding the first and the second vertical nanosheet respectively at a top, a bottom, and a left and a right sidewall thereof; and a first and a second source/drain region in contact with both the first vertical nanosheet and the second vertical nanosheet, wherein the first and the second vertical nanosheet and the gap between the first and the second vertical nanosheet are vertically above a raised portion of a backside inter-level dielectric (BILD) layer.
Clause 2: The semiconductor structure of clause 1, further comprising a sidewall spacer that separates the metal gate from the first source/drain region at a left side of the first vertical nanosheet and at a right side of the second vertical nanosheet, and an inner spacer that separates the metal gate from the first source/drain region at the gap between the first and the second vertical nanosheet.
Clause 3: The semiconductor structure of clause 2, wherein the inner spacer is materially different from the sidewall spacer or has a thickness that is different from a thickness of the sidewall spacer.
Clause 4: The semiconductor structure of clause 1, wherein the raised portion of the BILD layer has a left sidewall that is substantially aligned with the left sidewall of the first vertical nanosheet; has a right sidewall that is substantially aligned with the right sidewall of the second vertical nanosheet; and has a substantially flat top surface.
Clause 5: The semiconductor structure of clause 1, further comprising one or more shallow-trench-isolation (STI) regions being embedded in the BILD layer, the one or more STI regions surrounding the raised portion of the BILD layer.
Clause 6: The semiconductor structure of clause 1, further comprising a backside source/drain contact that contacts the second source/drain region of the vertical nanosheet transistor.
Clause 7: The semiconductor structure of clause 1, further comprising a placeholder underneath the first source/drain region of the vertical nanosheet transistor, the placeholder being embedded in the BILD layer and materially different from the BILD layer.
Clause 8: The semiconductor structure of clause 1, wherein the vertical nanosheet transistor is a first vertical nanosheet transistor, further comprising a second vertical nanosheet transistor, wherein a metal gate of the second vertical nanosheet transistor is insulated from the metal gate of the first vertical nanosheet transistor by a gate-cut structure, the gate-cut structure extends into a shallow-trench-isolation (STI) region embedded in the BILD layer.
Clause 9: A method of forming a semiconductor structure comprising forming a set of vertical nanosheets on top of a substrate, the set of vertical nanosheets includes a first and a second vertical nanosheet that are separated by a protective layer; forming a set of sacrificial gates covering portions of the set of vertical nanosheets; forming sidewall spacers at sidewalls of the set of sacrificial gates; recessing the set of vertical nanosheets between the set of sacrificial gates to create end surfaces of the set of vertical nanosheets and end surfaces of the protective layer; epitaxially growing a source/drain region from the end surfaces of the set of vertical nanosheets; replacing the set of sacrificial gates with a set of metal gates; and forming a backside source/drain contact from a backside of the substrate, the backside source/drain contact contacting a bottom surface of the source/drain region.
Clause 10: The method of clause 9, further comprising creating recesses at the end surfaces of the protective layer; and filling the recesses with a dielectric material to form inner spacers, the inner spacers being at least partially underneath the sidewall spacers.
Clause 11: The method of clause 9, further comprising, before epitaxially growing the source/drain region, forming one or more placeholders in the substrate between the set of sacrificial gates.
Clause 12: The method of clause 9, further comprising selectively etching the substrate, using the first and the second vertical nanosheet and the protective layer between the first and the second vertical nanosheet as an etch mask, to create one or more recesses; and filling the one or more recesses with a dielectric material to form one or more shallow-trench-isolation (STI) regions.
Clause 13: The method of clause 9, wherein forming the backside source/drain contact comprises replacing the substrate with a backside inter-level dielectric (BILD) layer; creating an opening in the BILD layer to expose a placeholder; selectively removing the exposed placeholder to further extend the opening thereby exposing a bottom surface of the source/drain region; and filling the extended opening with a conductive material to form the backside source/drain contact.
Clause 14: The method of clause 9, further comprising performing a gate-cut in the set of metal gates to form a gate-cut structure that extends into a shallow-trench-isolation (STI) region embedded in the substrate.
Clause 15: A semiconductor structure comprising a vertical nanosheet transistor, the vertical nanosheet transistor comprising a first and a second vertical nanosheet horizontally separated by a gap; a metal gate surrounding the first and the second vertical nanosheet and filling the gap between the first and the second vertical nanosheet; and a first and a second source/drain region in contact with both the first vertical nanosheet and the second vertical nanosheet, wherein the first and the second vertical nanosheet and the gap between the first and the second vertical nanosheet are vertically above a raised portion of a backside inter-level dielectric (BILD) layer, the raised portion of the BILD layer has a left sidewall that is substantially aligned with a left sidewall of the first vertical nanosheet; has a right sidewall that is substantially aligned with a right sidewall of the second vertical nanosheet; and has a substantially flat top surface.
Clause 16: The semiconductor structure of clause 15, further comprising a sidewall spacer that separates the metal gate from the first source/drain region, at a first end and a left side of the first vertical nanosheet and at a first end and a right side of the second vertical nanosheet, and an inner spacer that separates the metal gate from the first source/drain region at the first end of the first and the second vertical nanosheet and in the gap between the first and the second vertical nanosheet, wherein the inner spacer is materially different from the sidewall spacer or has a thickness that is different from a thickness of the sidewall spacer.
Clause 17: The semiconductor structure of clause 15, further comprising one or more shallow-trench-isolation (STI) regions being embedded in the BILD layer, the one or more STI regions surrounding the raised portion of the BILD layer.
Clause 18: The semiconductor structure of clause 17, further comprising a backside source/drain contact that contacts the second source/drain region of the vertical nanosheet transistor, wherein the backside source/drain contact is partially surrounded by the STI regions in a first direction along a width of the metal gate and is embedded in the BILD layer in a second direction along a length of the metal gate that is perpendicular to the first direction.
Clause 19: The semiconductor structure of clause 15, further comprising a placeholder underneath the first source/drain region of the vertical nanosheet transistor, the placeholder is embedded in the BILD layer and is materially different from the BILD layer.
Clause 20: The semiconductor structure of clause 15, wherein the vertical nanosheet transistor is a first vertical nanosheet transistor, further comprising a second vertical nanosheet transistor, wherein a metal gate of the second vertical nanosheet transistor is insulated from the metal gate of the first vertical nanosheet transistor by a gate-cut structure, the gate-cut structure extends into a shallow-trench-isolation (STI) region embedded in the BILD layer.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a vertical nanosheet transistor, the vertical nanosheet transistor comprising:
a first and a second vertical nanosheet horizontally separated by a gap;
a metal gate surrounding the first and the second vertical nanosheet respectively at a top, a bottom, and a left and a right sidewall thereof; and
a first and a second source/drain region in contact with both the first vertical nanosheet and the second vertical nanosheet,
wherein the first and the second vertical nanosheet and the gap between the first and the second vertical nanosheet are vertically above a raised portion of a backside inter-level dielectric (BILD) layer.

2. The semiconductor structure of claim 1, further comprising a sidewall spacer that separates the metal gate from the first source/drain region at a left side of the first vertical nanosheet and at a right side of the second vertical nanosheet, and an inner spacer that separates the metal gate from the first source/drain region at the gap between the first and the second vertical nanosheet.

3. The semiconductor structure of claim 2, wherein the inner spacer is materially different from the sidewall spacer or has a thickness that is different from a thickness of the sidewall spacer.

4. The semiconductor structure of claim 1, wherein the raised portion of the BILD layer has a left sidewall that is substantially aligned with the left sidewall of the first vertical nanosheet; has a right sidewall that is substantially aligned with the right sidewall of the second vertical nanosheet; and has a substantially flat top surface.

5. The semiconductor structure of claim 1, further comprising one or more shallow-trench-isolation (STI) regions being embedded in the BILD layer, the one or more STI regions surrounding the raised portion of the BILD layer.

6. The semiconductor structure of claim 1, further comprising a backside source/drain contact that contacts the second source/drain region of the vertical nanosheet transistor.

7. The semiconductor structure of claim 1, further comprising a placeholder underneath the first source/drain region of the vertical nanosheet transistor, the placeholder being embedded in the BILD layer and materially different from the BILD layer.

8. The semiconductor structure of claim 1, wherein the vertical nanosheet transistor is a first vertical nanosheet transistor, further comprising a second vertical nanosheet transistor, wherein a metal gate of the second vertical nanosheet transistor is insulated from the metal gate of the first vertical nanosheet transistor by a gate-cut structure, the gate-cut structure extends into a shallow-trench-isolation (STI) region embedded in the BILD layer.

9. A method of forming a semiconductor structure comprising:
forming a set of vertical nanosheets on top of a substrate, the set of vertical nanosheets includes a first and a second vertical nanosheet that are separated by a protective layer;
forming a set of sacrificial gates covering portions of the set of vertical nanosheets;
forming sidewall spacers at sidewalls of the set of sacrificial gates;
recessing the set of vertical nanosheets between the set of sacrificial gates to create end surfaces of the set of vertical nanosheets and end surfaces of the protective layer;
epitaxially growing a source/drain region from the end surfaces of the set of vertical nanosheets;
replacing the set of sacrificial gates with a set of metal gates; and
forming a backside source/drain contact from a backside of the substrate, the backside source/drain contact contacting a bottom surface of the source/drain region.

10. The method of claim 9, further comprising:
creating recesses at the end surfaces of the protective layer; and
filling the recesses with a dielectric material to form inner spacers, the inner spacers being at least partially underneath the sidewall spacers.

11. The method of claim 9, further comprising, before epitaxially growing the source/drain region, forming one or more placeholders in the substrate between the set of sacrificial gates.

12. The method of claim 9, further comprising:
selectively etching the substrate, using the first and the second vertical nanosheet and the protective layer between the first and the second vertical nanosheet as an etch mask, to create one or more recesses; and
filling the one or more recesses with a dielectric material to form one or more shallow-trench-isolation (STI) regions.

13. The method of claim 9, wherein forming the backside source/drain contact comprises:
replacing the substrate with a backside inter-level dielectric (BILD) layer;
creating an opening in the BILD layer to expose a placeholder;
selectively removing the exposed placeholder to further extend the opening thereby exposing the bottom surface of the source/drain region; and
filling the extended opening with a conductive material to form the backside source/drain contact.

14. The method of claim 9, further comprising performing a gate-cut in the set of metal gates to form a gate-cut structure that extends into a shallow-trench-isolation (STI) region embedded in the substrate.

15. A semiconductor structure comprising:
a vertical nanosheet transistor, the vertical nanosheet transistor comprising:
a first and a second vertical nanosheet horizontally separated by a gap;
a metal gate surrounding the first and the second vertical nanosheet and filling the gap between the first and the second vertical nanosheet; and
a first and a second source/drain region in contact with both the first vertical nanosheet and the second vertical nanosheet,
wherein the first and the second vertical nanosheet and the gap between the first and the second vertical nanosheet are vertically above a raised portion of a backside inter-level dielectric (BILD) layer, the raised portion of the BILD layer has a left sidewall that is substantially aligned with a left sidewall of the first vertical nanosheet; has a right sidewall that is substantially aligned with a right sidewall of the second vertical nanosheet; and has a substantially flat top surface.

16. The semiconductor structure of claim 15, further comprising a sidewall spacer that separates the metal gate from the first source/drain region, at a first end and a left side of the first vertical nanosheet and at a first end and a right side of the second vertical nanosheet, and an inner spacer that separates the metal gate from the first source/drain region at the first end of the first and the second vertical nanosheet and in the gap between the first and the second vertical nanosheet, wherein the inner spacer is materially different from the sidewall spacer or has a thickness that is different from a thickness of the sidewall spacer.

17. The semiconductor structure of claim 15, further comprising one or more shallow-trench-isolation (STI) regions being embedded in the BILD layer, the one or more STI regions surrounding the raised portion of the BILD layer.

18. The semiconductor structure of claim 17, further comprising a backside source/drain contact that contacts the second source/drain region of the vertical nanosheet transistor, wherein the backside source/drain contact is partially surrounded by the STI regions in a first direction along a width of the metal gate and is embedded in the BILD layer in a second direction along a length of the metal gate that is perpendicular to the first direction.

19. The semiconductor structure of claim 15, further comprising a placeholder underneath the first source/drain region of the vertical nanosheet transistor, the placeholder is embedded in the BILD layer and is materially different from the BILD layer.

20. The semiconductor structure of claim 15, wherein the vertical nanosheet transistor is a first vertical nanosheet transistor, further comprising a second vertical nanosheet transistor, wherein a metal gate of the second vertical nanosheet transistor is insulated from the metal gate of the first vertical nanosheet transistor by a gate-cut structure, the gate-cut structure extends into a shallow-trench-isolation (STI) region embedded in the BILD layer.
